(19) United States
(12) Patent Application Publication
(10) Pub. No.: US 2005/0272393 A1
(43) Pub. Date: Dec. 8, 2005

(54) Miniaturized television tuner

(75) Inventors: Masaki Yamamoto, Tokyo (JP); Masaaki Endo, Tokyo (JP)

Correspondence Address: BRINKS HOFER GILSON & LIONE, P.O. BOX 10395, CHICAGO, IL, 60610, US

(73) Assignee: ALPS ELECTRIC CO., LTD.

(21) Appl. No.: 11/145,657

(22) Filed: Jun. 6, 2005

(30) Foreign Application Priority Data
Jun. 8, 2004 (JP) 2004-169610

(51) Int. Cl. H05K 9/00

(52) U.S. Cl. 455/300; 348/731

(57) ABSTRACT

A television tuner includes a square metal frame; a tuner part that converts a television signal into an intermediate frequency signal and located at the side of a first plate in the frame adjacent to a second plate, from the second plate toward a third plate; an intermediate frequency circuit part, which demodulates the intermediate frequency signal and outputs a picture signal and an audio signal, and is located at the side of a fourth plate adjacent to the second plate, from the third plate side toward the second plate side; and a surface mounting type board-to-board connector which has an input terminal of the television signal, an output terminal of the picture signal and an output terminal of the audio signal on its top surface. The board-to-board connector is disposed close to approximately the center of the second plate.

### BACKGROUND OF THE INVENTION

1. Field of the Invention

The present invention relates to a television tuner suitable for portable devices, etc.

2. Description of the Related Art

A conventional television tuner will be described with reference to FIG. 2. The interior of a metal frame 1 is bisected into a first sectional region 1e at the side of a first lateral plate 1a and a second sectional region 1f at the side of a second lateral plate 1b by means of a shield plate 2 that bridges a third lateral plate 1c and a fourth lateral plate 1d opposite to the third lateral plate 1c. A connector 3 for receiving a television signal is also attached to the third lateral plate 1c at a location corresponding to the second sectional region 1f. Further, a circuit substrate (not shown) constituting a circuitry is contained within the metal frame 1.

In the second sectional region 1f, a tuner part 4 that converts an input television signal into an intermediate frequency signal is formed on the circuit substrate. The tuner part 4 includes an antenna tuning circuit 4a, a high frequency amplifier circuit 4b, an interstage tuning circuit 4c, an oscillation circuit 4d, a mixer circuit 4e and the like. Each of the circuits is designed to be suitable for the specifications such as NTSC mode or PAL mode. The antenna tuning circuit 4a is disposed at a location close to the connector 3, and the oscillation circuit 4d and the mixer circuit 4e are disposed at the side of the fourth lateral plate 1d.

In the first sectional region 1e, a picture intermediate frequency circuit part 5, which detects an intermediate frequency signal and outputs a picture signal and an audio signal, is formed on the circuit substrate. The picture intermediate frequency circuit part 5 includes a SAW filter 5a, an IC for detection (an integrated circuit) 5b, an oscillation circuit 5c, and so on. Each of the circuits is designed to be suitable for the specifications such as NTSC mode or PAL mode. The SAW filter 5a is disposed at the side of the fourth lateral plate 1d within the first sectional region 1e. Further, to the first lateral plate 1a is attached a plurality of terminals 6 which are arranged in the form of a column at a predetermined distance. These terminals 6 are used to supply power to the tuner part 4 or the picture intermediate frequency circuit part 5, input a channel selection signal to the tuner part 4, and output the picture signal and the audio signal from the picture intermediate frequency circuit part 5. They are connected to the tuner part 4 and the picture intermediate frequency circuit part 5.

Therefore, the first sectional region 1e and the second sectional region 1f are formed within the area of the first lateral plate 1a to which the terminals 6 are attached, and the tuner part 4 and the picture intermediate frequency circuit part 5 are formed in the second sectional region 1f and the first sectional region 1e, respectively. It is thus possible to reduce the area of a mother substrate of a television receiver, for attaching the tuner part.

Furthermore, since the first sectional region 1e and the second sectional region 1f are bisected by means of the shield plate 2, interference between the tuner part 4 and the picture intermediate frequency circuit part 5 is lowered.

In the aforementioned construction, the television signal input through the connector 3 is selected and amplified by the tuning circuits 4a and 4c, and the high frequency amplifier circuit 4b, and is then converted into the intermediate frequency signal through the mixer circuit 4e. The intermediate frequency signal output from the mixer circuit 4e is input to the SAW filter 5a and is then detected by the IC for detection (the integrated circuit) 5b. Thus, the picture signal and the audio signal are output from the IC for detection 5b. Since the mixer circuit 4e of the tuner part 4 and the SAW filter 5c of the picture intermediate frequency circuit part 5 are formed in the region at the side of the fourth lateral plate 1d, connection between the mixer circuit 4e and the SAW filter 5c can be made in the shortest way. The picture signal and the audio signal are output through the terminals 6 (e.g., see Japanese Registered Utility Model No. 3096173 (FIG. 1)).

The conventional television tuner shown in FIG. 2 is a television tuner which is erected on a mother substrate, wherein the connector that receives the television signal is attached to one lateral plate of the metal frame, and the terminal for use in power, the output terminal, etc. are attached to the other lateral plate. Although this television tuner is miniaturized, however, it cannot be used for portable devices such as mobile phones.

### SUMMARY OF THE INVENTION

The present invention has been finalized in view of the drawbacks, and an advantage of the invention is that it provides a miniaturized television tuner in which connection to a mother substrate can be made only through a connector, and the path of a signal from the input of a television signal to the output of a picture signal, etc. can become the shortest on the basis of the connector.

In order to accomplish the above, according to the invention, there is provided a television tuner, including a square frame made of a metal plate, a circuit substrate contained within the frame, a tuner part that converts a television signal into an intermediate frequency signal, an intermediate frequency circuit part, which demodulates the intermediate frequency signal and produces a picture signal and an audio signal, and a board-to-board connector of a surface mounting type, which has at least an input terminal of the television signal, an output terminal of the picture signal and an output terminal of the audio signal on its top surface. In this case, the board-to-board connector is disposed at a location on the circuit substrate, which is close to approximately the center of a first lateral plate in the frame. An input tuning circuit, a high frequency amplifier circuit, an interstage tuning circuit and a mixer circuit, all of which form the tuner part, are sequentially disposed in a region of the circuit substrate, which is located at the side of a second lateral plate adjacent to the first lateral plate, from the first lateral plate toward a fourth lateral plate. Further, a SAW filter and a demodulation circuit, which constitute the intermediate frequency circuit part, are disposed in a region of the circuit substrate, which is located at the side of a third lateral plate adjacent to the first lateral plate, from the fourth lateral plate toward the first lateral plate.

Furthermore, the tuner part can include an UHF tuner part and a VHF tuner part. In this case, the UHF tuner part is disposed at the side of the second lateral plate.

Furthermore, the tuner part can include an oscillation circuit that applies a local oscillation signal to the mixer circuit. A resonant circuit constituting the oscillation circuit is also disposed close to the region in which the fourth lateral plate is located than to the region in which the mixer circuit is located.

Further, the board-to-board connector can have the respective terminals arranged in the form of a column. The board-to-board connector can also be disposed in such a manner that the arrangement direction of each of the terminals is parallel to the first lateral plate.

An intermediate frequency tuning circuit is further located between the mixer circuit and the SAW filter in a region interposed between the region in which the tuner part is located and the region in which the intermediate frequency circuit part is located.

Further, the circuit substrate can be comprised of a ceramic substrate. Wiring patterns and resistor elements in the tuner part and the intermediate frequency circuit part can be formed by means of thick film printing.

In accordance with a first aspect of the invention, a board-to-board connector is disposed at a location on the circuit substrate, which is close to approximately the center of the first lateral plate in the frame. An input tuning circuit, a high frequency amplifier circuit, an interstage tuning circuit and a mixer circuit, which form a tuner part, are sequentially disposed in a region of the circuit substrate, which is located at the side of a second lateral plate adjacent to the first lateral plate, from the first lateral plate side toward a fourth lateral plate side. Furthermore, a SAW filter and a demodulation circuit which constitute an intermediate frequency circuit part are sequentially disposed in a region of the circuit substrate, which is located at the side of a third lateral plate adjacent to the first lateral plate, from the fourth lateral plate side toward the first lateral plate side. Thus, a television signal can be input from one terminal of the board-to-board connector to the tuner part, an intermediate frequency signal can be input from the tuner part to the intermediate frequency circuit part at the side of the fourth lateral plate, and the picture signal and the audio signal being final output signals can be output to the other terminal of the board-to-board connector at the side of the first lateral plate. As such, since respective circuits can be connected without twists and turns in the flow of the signal, it is possible to minimize transmission loss and also to realize miniaturization.

In accordance with a second aspect of the invention, the tuner part has an UHF tuner part and a VHF tuner part. The UHF tuner part is disposed at the side of the second lateral plate. Thus, since the second lateral plate for use in ground becomes close thereto, the circuit operation of the UHF tuner part having a high frequency can be stabilized.

In accordance with a third aspect of the invention, the tuner part includes an oscillation circuit that applies a local oscillation signal to the mixer circuit. Further, a resonant circuit constituting the oscillation circuit is located close to the region in which the fourth lateral plate is located than to the region in which the mixer circuit is located. Therefore, since the resonant circuit and other circuits are separated from each other, it is possible to mitigate obstruction, which affects other circuits, due to radiation of the oscillation signal from the resonant circuit.

In accordance with a fourth aspect of the invention, the board-to-board connector has the terminals arranged in the form of a column. The board-to-board connector is also disposed in such a manner that the arrangement direction of each of the terminals is parallel to the first lateral plate. Accordingly, the output side of the tuner part and the input side of the intermediate frequency circuit part can be made close to each other.

In accordance with a fifth aspect of the invention, an intermediate frequency tuning circuit is further located between the mixer circuit and the SAW filter in a region interposed between the region in which the tuner part is located and the region in which the intermediate frequency circuit part is located. It is therefore possible to supply an intermediate frequency signal from the tuner part to the intermediate frequency circuit part in the shortest distance.

In accordance with a sixth aspect of the invention, the circuit substrate is comprised of a ceramic substrate. Wiring patterns and resistor elements in the tuner part and the intermediate frequency circuit part are formed by means of thick film printing. This makes it possible to realize further miniaturization.

### BRIEF DESCRIPTION OF THE DRAWINGS

FIG. 1 is a diagram showing a circuit layout of a television tuner according to the present invention; and

FIG. 2 is a diagram showing a circuit layout of a conventional television tuner.

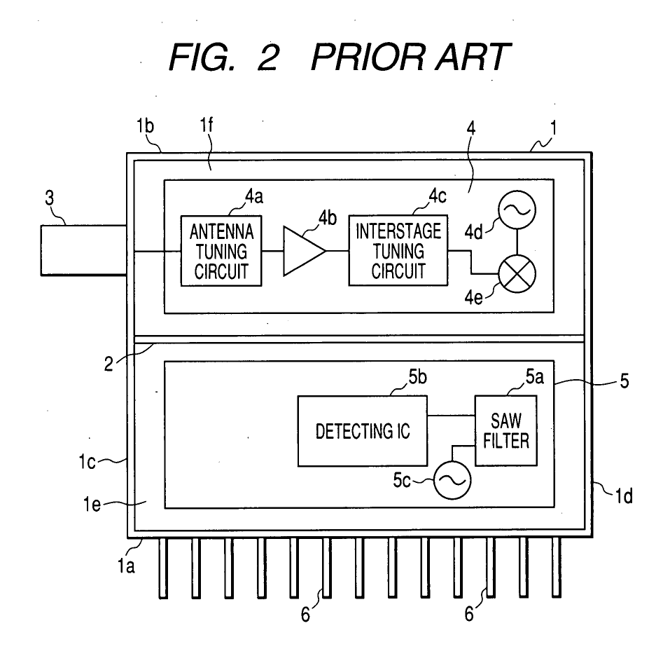

### DESCRIPTION OF THE PREFERRED EMBODIMENT

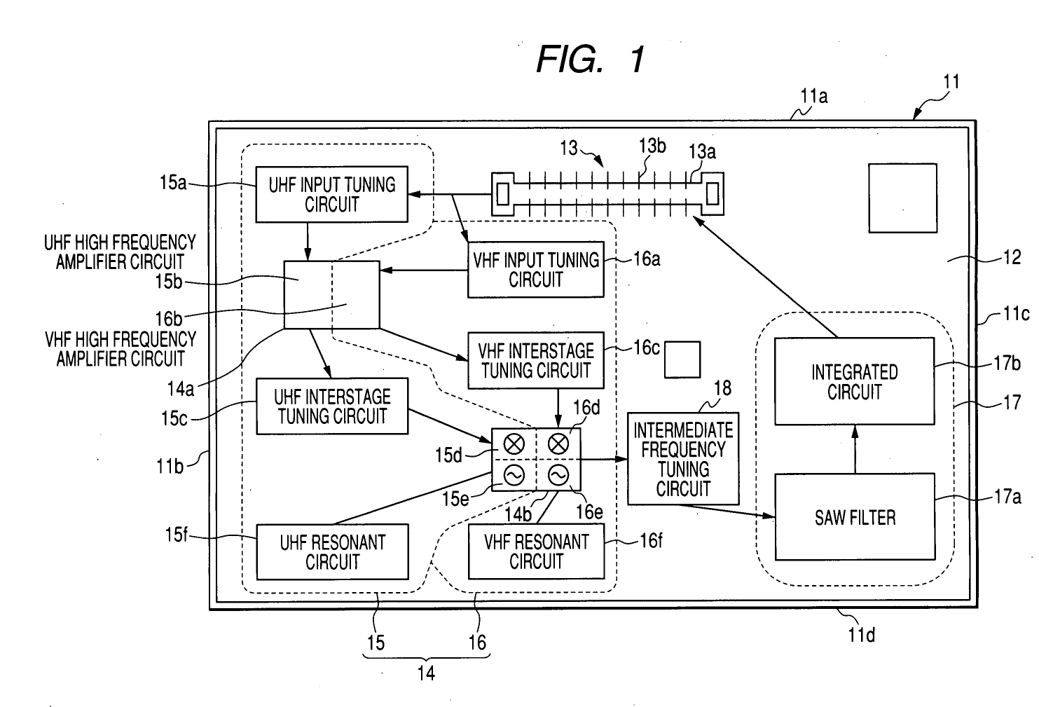

A television tuner according to the present invention will now be described with reference to FIG. 1. A square frame 11 made of a metal plate includes first to fourth lateral plates 11a to 11d. The first lateral plate 11a and the fourth lateral plate 11d are opposite to each other, and the second lateral plate 11b and the third lateral plate 11c are opposite to each other. A circuit substrate 12 made of a ceramic material is contained within the frame 11.

A board-to-board connector 13 is formed on the circuit substrate 12 approximately at the center of the first lateral plate 11a of the frame 11. The board-to-board connector 13 includes an insulating base 13a of a strip shape, and a plurality of terminals 13b that are projected in the form of a column along the side of the insulating base 13a. A part of each of the terminals 13b is exposed on a top surface of the insulating base 13a. The board-to-board connector 13 is disposed parallel to the first lateral plate 11a, and each of the terminals 13b is soldered to a connection conductor (not shown) formed in the circuit substrate 12.

The board-to-board connector 13 is a female type. A board-to-board connector (not shown) of a male type, which is fitted into the board-to-board connector 13, is attached to a mother substrate (not shown). Further, a television signal is input from the mother substrate to the circuit substrate 12 through the board-to-board connector 13.

On the circuit substrate 12 are formed a tuner part 14 that converts the television signal into an intermediate frequency signal, and an intermediate frequency circuit part 17 that demodulates the intermediate frequency signal. The tuner part 14 is formed in a region of the circuit substrate 12, which is located at the side of the second lateral plate 11b. Further, the intermediate frequency circuit part 17 is formed in a region of the circuit substrate 12, which is located at the side of the third lateral plate 11c opposite to the second lateral plate 11b.

The tuner part 14 consists of an UHF tuner part 15 and a VHF tuner part 16. The UHF tuner part 15 has an UHF input tuning circuit 15a, an UHF high frequency amplifier circuit 15b, an UHF interstage tuning circuit 15c, an UHF mixer circuit 15d and an UHF oscillation circuit 15e.

In the same manner, the VHF tuner part 16 includes a VHF input tuning circuit 16a, a VHF high frequency amplifier circuit 16b, a VHF interstage tuning circuit 16c, a VHF mixer circuit 16d, and a VHF oscillation circuit 16e. Of them, the UHF high frequency amplifier circuit 15b and the VHF high frequency amplifier circuit 16b are formed within the same integrated circuit 14a. Further, the UHF mixer circuit 15d and the UHF oscillation circuit 15e (except for a resonant circuit), and the VHF mixer circuit 16d and the VHF oscillation circuit 16e (except for a resonant circuit) are formed within the same integrated circuit 14b. A PLL circuit (not shown) is also formed within the integrated circuit 14b.

The UHF resonant circuit 15f connected to the UHF oscillation circuit 15e and the VHF resonant circuit 16f connected to the VHF oscillation circuit 16e are located outside the integrated circuit 14b.

Furthermore, the UHF tuner part 15 rather than the VHF tuner part 16 is located close to the second lateral plate 11b. The UHF input tuning circuit 15a, the integrated circuit 14a, the UHF interstage tuning circuit 15c and the UHF resonant circuit 15f are sequentially disposed from the first lateral substrate 11a toward the fourth lateral plate 11d. The VHF tuner part 16 is also located adjacent to the region in which the UHF tuner part 15 is formed. The VHF input tuning circuit 16a, the VHF interstage tuning circuit 16c, the integrated circuit 14b and the VHF resonant circuit 16f are also sequentially disposed from the first lateral plate 11a toward the fourth lateral plate 11d. The location where the integrated circuit 14a is disposed is the middle of the VHF input tuning circuit 16a and the VHF interstage tuning circuit 16c with respect to the first and fourth lateral plates 11a and 11d. Further, the UHF resonant circuit 15f is located closer to the fourth lateral plate 11d than to the location where the integrated circuit 14a is located.

Meanwhile, the intermediate frequency circuit part 17 includes a SAW filter 17a that receives an intermediate frequency signal, and an integrated circuit 17b that demodulates the intermediate frequency signal output from the SAW filter 17a. The integrated circuit 17b has a demodulation circuit, and peripheral circuits necessary for demodulation (an oscillation circuit for sync detection, etc.). The integrated circuit 17b outputs a picture signal, an audio signal, and so on. The SAW filter 17a is located at the side of the fourth lateral plate 11d, and the integrated circuit 17b rather than the SAW filter 17a is located close to the first lateral plate 11a.

Further, an intermediate frequency tuning circuit 18 is interposed between the region in which the VHF tuner part 16 is formed and the region in which the intermediate frequency circuit part 17 is formed. The intermediate frequency tuning circuit 18 is interposed between the UHF mixer circuit 15d and the VHF mixer circuit 16d, and the SAW filter 17a.

Furthermore, a chip-shaped passive element or active element for forming each circuit, or an integrated circuit is mounted in the region in which each of the circuits is disposed as described above. Wiring patterns for interconnecting the respective circuit components, etc. resistor elements having a loose variation range, and the like are formed by means of thick film printing. In addition, the VHF tuner part 16 generally receives a wide band using the tuning circuit of a band switch type. In this case, when the reception range of the band is made to be narrower a little, a tuning circuit of a ratio band switch type can be adopted. It makes it possible to realize a very small television tuner having 18 mm×25 mm×3 mm (width, length, height).

Further, the terminal 13b of the board-to-board connector 13, which is located the closest to the second lateral plate 11b is used as an input terminal of the television signal. The television signal can be thus input to the tuner part 14 in the shortest distance. This is effective in avoiding signal loss and hindrance from other circuits. Furthermore, the signal flows in the direction of arrows, and the intermediate frequency signal is output toward the fourth lateral plate 11d. It is thus possible to input those signals to the intermediate frequency circuit part 17 in the shortest distance. Moreover, the terminal 13b of the board-to-board connector 13, which is located the closest to the third lateral plate 11c, can be used as an output terminal. This causes the picture signal and the audio signal to be output in the shortest distance.

As clearly described above, the television signal is input from one terminal of the board-to-board connector 13 to the tuner part 14, the intermediate frequency signal is input from the tuner part 14 to the intermediate frequency circuit part 17 at the side of the fourth lateral plate 11d, and the picture signal and the audio signal being final output signals are output to the other terminal of the board-to-board connector 13 at the side of the first lateral plate 11a. Accordingly, since there is no meandering in the flow of a signal, transmission loss can be minimized.

Further, the UHF tuner part 15 having a high frequency, rather than the VHF tuner part 16, is located close to the second lateral plate 11b. This allows the UHF tuner part 15 to be easily grounded to the second lateral plate 11b, thereby stabilizing the operation of the circuit.

1. A television tuner, comprising:
a square frame made of a metal plate;
a circuit substrate contained within the frame;
a tuner part that converts a television signal into an intermediate frequency signal;
an intermediate frequency circuit part, which demodulates the intermediate frequency signal and outputs a picture signal and an audio signal;
a board-to-board connector of a surface mounting type, which has at least an input terminal of the television signal, an output terminal of the picture signal and an output terminal of the audio signal on a top surface, the board-to-board connector being disposed at a location on the circuit substrate, which is close to approximately a center of a first lateral plate in the frame;
an input tuning circuit, a high frequency amplifier circuit, an interstage tuning circuit and a mixer circuit, all of which form the tuner part, are sequentially disposed in a region of the circuit substrate, which is located at a side of a second lateral plate adjacent to the first lateral plate, from the first lateral plate toward a fourth lateral plate; and
a SAW filter and a demodulation circuit, which constitute the intermediate frequency circuit part, are sequentially disposed in a region of the circuit substrate, which is located at a side of a third lateral plate adjacent to the first lateral plate, from a fourth lateral plate side toward a first lateral plate side.

2. The television tuner according to claim 1,
wherein the tuner part includes an UHF tuner part and a VHF tuner part, and the UHF tuner part is disposed at the side of the second lateral plate.

3. The television tuner according to claim 1,
wherein the tuner part includes an oscillation circuit that applies a local oscillation signal to the mixer circuit, and
the oscillation circuit has a resonant circuit which is disposed close to a region in which the fourth lateral plate is located than to a region in which the mixer circuit is located.

4. The television tuner according to claim 1,
wherein the board-to-board connector has the respective terminals arranged in the form of a column, and the board-to-board connector is disposed such that an arrangement direction of each of the terminals is parallel to the first lateral plate.

5. The television tuner according to claim 1, further comprising:
an intermediate frequency tuning circuit that is located between the mixer circuit and the SAW filter in a region interposed between the region in which the tuner part is located and the region in which the intermediate frequency circuit part is located.

6. The television tuner according to claim 1,
wherein the circuit substrate is comprised of a ceramic substrate, and wiring patterns and resistor elements in the tuner part and the intermediate frequency circuit part are formed by means of thick film printing.
